(19) United States
(12) Patent Application Publication
(10) Pub. No.: US 2005/0098890 A1
(43) Pub. Date: May 12, 2005

(54) Method for producing an adhesive bond and adhesive bond between a chip and a planar surface

(76) Inventors: Stephan Blaszczak, Freyburg (DE); Martin Reiss, Dresden (DE); Bernd Scheibe, Dresden (DE)

Correspondence Address: SLATER & MATSIL, L.L.P., 17950 PRESTON RD, SUITE 1000, DALLAS, TX, 75252-5793, US

(21) Appl. No.: 10/962,197

(22) Filed: Oct. 8, 2004

(30) Foreign Application Priority Data
Oct. 8, 2003 (DE) 103 47 321.1

(51) Int. Cl. H01L 23/495

(52) U.S. Cl. 257/753

(57) ABSTRACT

A method for producing an adhesive bond between a chip and a planar surface and the arrangement of the adhesive bond are discussed. A flexible coupling medium is applied on the planar surface or on one side of the chip over the extent of its area and, of the surfaces to be bonded to each other. The surface that is free from the coupling agent is brought into contact with the coupling agent and remains in contact under the conditions required until a stable bond is produced. The adhesive bond is characterized in that the surfaces to be bonded to each other lie at a distance opposite each other and the coupling medium spreads at least virtually over the entire surface area of one of the two sides of the chip.

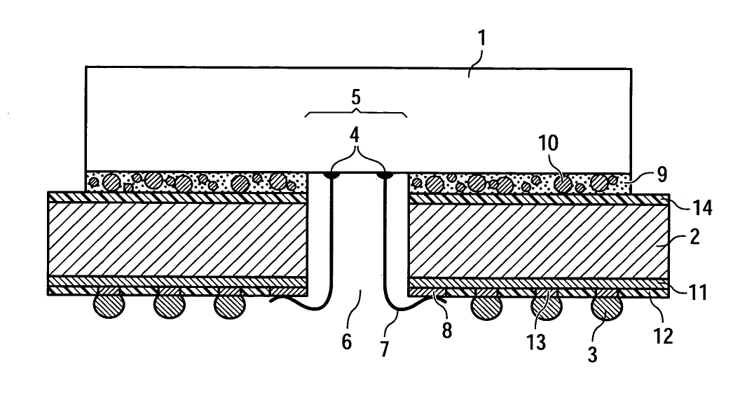

This application claims priority to German Patent Application 103 47 321.1, which was filed Oct. 8, 2003, and is incorporated herein by reference.

### TECHNICAL FIELD

The invention relates generally to device packages, and more particularly to a method for producing an adhesive bond between a chip and a planar surface.

### BACKGROUND

The invention also relates to an adhesive bond for attaching a chip on a planar surface by means of a flexible coupling medium, the surfaces to be bonded to each other lying at a distance opposite each other and the coupling medium spreading at least virtually over the entire backside of the chip or the entire active side of the chip, apart from a region serving for the electrical contacting.

As is known, the mechanical attachment of chips (die bonding) on a planar surface, in particular die bonding on a carrier substrate, is increasingly being performed by adhesion. An intended chip land area is generally provided with an adhesive serving as the coupling agent and the chip is subsequently set down on the land area in a defined manner. During the subsequent curing of the adhesive, in accordance with a pressure-temperature regime determined both by the material properties of the adhesive and by the application of the integrated chip, the adhesive is liquefied and the full-area, integrally locked bond between the chip surface and the substrate surface is realized. Apart from adhesive tapes, at present, pasty adhesives that can be applied by means of dispensing, stamping or printing are increasingly being used as the coupling medium.

Dependent on the different die bonding methods and the different applications of the integrated chip, there are a large number of adhesive materials that allow their properties to be adjusted very well and over a wide range. For example, apart from differing in their strength in the installed state, they also differ in their processing temperatures, wetting properties, material compositions and, as a result, in particular their thermal and electrical properties.

The full-area adhesive bond between a chip and a carrier substrate is subjected to a particular stress exposure, since, primarily due to the different coefficients of thermal expansion of the materials to be bonded, the silicon of the chip and the plastic of the substrate, under thermal loading such as that which occurs specifically during alternating temperature tests or burn-in, normal and shearing stresses act on the adhesive bond. The stress moments, some of which are extreme, may lead to the failure or malfunction of the component because of destruction of the adhesive bond, in particular if, after mounting of the chip in a package, it is exposed to second mounting, the integration of the package in the circuit, and consequently a further temperature change.

A customary method for stress reduction and for protection of the component is to use an adhesive material with high flexibility, whereby the layer of adhesive can absorb a large part of the stresses occurring between the component and the substrate. However, for this purpose it is necessary to maintain a minimum thickness, dependent on the respective chip size, of the layer of adhesive, which absorbs the stresses and ensures the equalization of stress within the layer. Setting and checking the distance is only possible, however, within the tolerances made possible by the equipment over the travelling path of the die bonding tool.

Even if the distance of the chip from the substrate can be set sufficiently accurately, there is a disadvantage of using high-viscosity adhesive materials in that there is a greater tendency for more or less pronounced canting of the chip with respect to the substrate surface, with the result that the two surfaces to be bonded to each other do not lie parallel to each other. This leads to uneven stress distribution within the adhesive bond, until there is rupturing of the adhesive bond, in particular if the thickness goes below the minimum required for stress equalization.

In principle, it is known to admix special fillers with the adhesive, known in particular from the preparation of isotropically or anisotropically electrically conductive adhesives. However, these are not suitable for reproducibly setting a defined distance against the defined pressing force, which the die bonding tool exerts on the adhesive bond while it is being produced. Therefore, the fillers of isotropically electrically conducting adhesive, which primarily consist of silver or gold in the form of platelets or flakes with proportions by weight of 60 to 80%, are designed with regard to their shape and amount specifically to leave the adhesive compressible during its liquefying phase, in order to achieve the greatest possible surface-area contact between the conductive platelets or flakes during the compression.

On the other hand, in anisotropically electrically conducting adhesive, conductive particles of primarily nickel, gold or metal-coated plastic beads are distributed with a much lower proportion by weight. The filling proportion in the case of this adhesive should be set such that it is not electrically conducting in any direction, but during die bonding some of the particles are always trapped between two corresponding contact areas and deformed, so that they exert a permanent pressure on the contact areas after the curing of the adhesive. Consequently, in the case of these filling bodies too, the deforming and resultant distance, set exclusively by the die bonding tool, between the surfaces to be mechanically and electrically connected is explicitly used principally for producing a reliable electrical connection. In addition, as described, such pressure-loaded contacts are very susceptible to rupture, however, and often lead to soldering defects, as a result of thermal loading.

To avoid the stress on electrically conducting adhesive joints of this type, in German Patent No. 100 64 411 A1 the particles of the filler are chosen to be much smaller than the distance between the contact areas. The electrical connection is in this case established by an alignment of the particles by means of a magnetic field for concatenation. A further possibility for producing the electrically conducting adhesive bond in a stress-free manner is described by the particles consisting of a solder and at the same time the softening temperature of the solder being made to match that of the adhesive, so that the particles take form in a stress-free state between the contact areas during the pressure-fixing of the adhesive joint and adapt themselves to the distance between the areas. Both embodiments are consequently characterized in that the fillers in the adhesive bond adapt themselves to the position of the contact surfaces with respect to each other that is predetermined by the equipment, which also corresponds to the actual object of the invention concerned.

A further major disadvantage of using high-viscosity adhesive materials lies in their poor wetting properties with respect to the surfaces to be bonded, which leads to greatly reduced reliability of the adhesive bond, in particular in conjunction with the disadvantages already discussed.

### SUMMARY OF THE INVENTION

Aspects of the invention relate to a method for producing an adhesive bond between a chip and a planar surface. A flexible coupling medium is applied on the planar surface or on one side of the chip over the extent of its area and of the surfaces to be bonded to each other. The surface that is free from coupling agent is subsequently brought into contact with the coupling agent and remains in contact under the conditions required for forming the bond until the coupling medium has formed a stable bond between the two surfaces.

Aspects of the invention also relate to an adhesive bond for attaching a chip on a planar surface by means of a flexible coupling medium, the surfaces to be bonded to each other lying at a distance opposite each other and the coupling medium spreading at least virtually over the entire backside of the chip or the entire active side of the chip, apart from a region serving for the electrical contacting.

### BRIEF DESCRIPTION OF THE DRAWINGS

The invention is to be explained in more detail below on the basis of an exemplary embodiment.

The Figure shows a sectional representation of a substrate-based chip package with an adhesive bond according to the invention.

The following list of reference symbols can be used in conjunction with the figure:
1 chip
2 carrier substrate
3 solder ball
4 electrical terminals
5 terminal region
6 through-hole
7 wire bridges
8 bonding pad
9 coupling medium, realized in the exemplary embodiment as a layer of adhesive
10 filling body
11 metallization
12 first solder stop mask
13 pad carrying solder ball
14 second solder stop mask

### DETAILED DESCRIPTION OF ILLUSTRATIVE EMBODIMENTS

Various embodiments of the present invention will now be described. One specific example will then be discussed with respect to the figure.

In a first embodiment, the invention provides an adhesive bond between a chip and a planar surface and a method for producing such an adhesive bond, the adhesive bond ensuring an approximately equal thickness of the coupling medium between the surfaces over the entire adhering area after the surfaces to be bonded have been brought together.

On the method side, an embodiment is achieved by a distance between the surfaces being set to a size that corresponds at least to a desired thickness of the coupling medium by the adhesive bond in such a way that it is self-leveling and approximately constant over the surface area. In particular, the self-leveling setting of the distance between the two surfaces to be bonded ensures that the distance is set independently of the tolerance of the travelling path of the die bonding tool, and consequently independently of any canting of this tool. Rather, the distance is established exclusively by conditions between the components involved in the adhesive bond, by the position of the surfaces to be bonded in relation to each other and the filling bodies lying in between, acting as spacers. This comprises the main pre-requisite for producing a virtually uniform distance over the entire bonding surface.

The fact that a defined desired thickness of the coupling medium is thereby maintained, dependent primarily on the viscosity of the adhesive material and on the chip size, and as a consequence on the normal stress to be expected as a result of different bowing of the bonded surfaces under thermal loading and the shearing stress to be expected as a result of the different thermal expansion of the bonded materials, means that the flexible property of the bond, with respect to lateral movements and distance-increasing movements, that is required for absorbing the stresses within the bond is established.

One particularly advantageous embodiment therefore provides that filling bodies with a round cross-section and a defined diameter, at least some of which have a maximum diameter which correspond at most to the distance to be set, are admixed with the coupling medium. The filling bodies serve here as it were as an internal limit switch for the travelling path of the die bonding tool. Filling bodies with a round cross-section are especially suitable for arranging themselves next to one another, and consequently setting the distance to the size of the diameter, in the phase of forming the bond in which the viscosity of the coupling medium is reduced and the surfaces are joined together with a defined pressure being applied. Both spherical and cylindrical filling bodies are suitable for this, provided that, on the one hand, they serve as spacers and are therefore solid enough that they scarcely deform under the effect of the pressure applied and, on the other hand, they are just flexible enough that they can absorb the pressure, in order not to be destroyed under the effect of the pressure applied.

Furthermore, whether the filling bodies are admixed with the coupling medium before it is applied or the filling bodies are introduced afterwards, in this case by applying them to the surface and subsequently pressing them in during the sequence followed in the method of producing the bond, depends on the one hand on the properties of the coupling medium and on the other hand on the technological requirements.

Whether the filling bodies have a different diameter or the same diameter, corresponding to different refinements of the invention, depends in particular on the viscosity of the coupling medium. In high-viscosity coupling media, a movement of the filling bodies for the alignment next to one another is more easily possible, so that stacking of the filling bodies does not occur, whereas stacking must be actively prevented in low-viscosity coupling media. Introducing filling bodies with a much smaller diameter has the effect that the large filling bodies, defining the distance, roll to a certain extent away from the small bodies and in turn arrange themselves next to one another. The use of lower-viscosity coupling medium is therefore particularly advantageous, since such a coupling medium generally has better wetting properties and consequently leads to more reliable adhesive bonds.

With the use of a pasty adhesive that is capable of being printed as the coupling medium, in an advantageous embodiment of the invention, the advantages of the various known possibilities of applying the coupling medium, for example by screen printing, can be used.

Similarly, the properties of the coupling medium can be changed in a known way by adding further additives that set selected properties, such as for example electrically conductive particles or particles influencing the mechanical strength.

A particularly advantageous form of the invention provides that the adhesive bond between a chip and a carrier substrate is produced in order in particular to perform the packaging of the chip. In this case it is possible both for the chip to be attached with the active side downwards (face-down), with corresponding formation of the carrier substrate and configuration of the electrical contacting, and for it to be attached with the active side upwards (face-up).

On the arrangement side, the object is achieved by filling bodies with a round cross-section and defined diameter being arranged next to one another in the coupling medium and the diameter corresponding at most to the distance between the surfaces to be bonded. As a result of the defined diameter, the arrangement of the filling bodies next to one another within the adhesive bond ensures the maintenance of a distance of a size exactly corresponding to the diameter. As a result of the round cross section, and in particular if the filling bodies are spherical bodies, in a way corresponding to a particularly advantageous embodiment of the invention, dependence of the distance on the alignment of the filling bodies is prevented.

If the filling bodies have at least two different diameters, as provided in a further adhesive bond according to the invention, the smaller filling bodies merely serve, as described above, for the self-leveling alignment of the larger filling bodies of a virtually uniform size, serving as spacers. Since a stacking effect is to be prevented by the presence of the smaller filling bodies, they are not involved in the setting of the distance and should preferably be approximately of such a size that they fit into the void which is formed by two adjacent filling bodies setting the distance and one of the surfaces to be bonded. However, the size of the smaller filling bodies is always determined by the properties of the coupling medium and principally by its viscosity, in order to ensure the alignment of the large filling bodies next to one another during the adhering process.

In a way corresponding to a refinement of the invention, the filling bodies acting as spacers in the adhesive bond while it is being produced are reversibly deformable. This makes them capable of absorbing pressure peaks, which act on the coupling medium, and possibly also on the filling bodies, while the surfaces to be bonded are brought together, in particular as a result of their canting in relation to each other. Since they remain in the adhesive bond, they can additionally absorb stresses which occur in the interior of the finished adhesive bond as a result of different bowing of the different bonded materials under thermal loading in the direction of the filling bodies.

To be able also to adapt this property of the filling bodies to the different applications and process conditions, a further formation of the adhesive bond according to the invention provides that the reversible deformability of the filling bodies differs. For example, in the case of larger chips there is both a greater absolute deviation from the parallel alignment of the surfaces to be bonded in relation to each other, and consequently greater pressure peaks when they are brought together, and greater bowing of the surfaces, differing from each other, under thermal loading, and consequently higher stresses within the adhesive bond.

The filling bodies according to the invention are suitable in particular to be added to a coupling medium if the latter is a pasty adhesive that is capable of being printed, since a homogeneous distribution in the latter is possible by appropriate mixing processes. Furthermore, adhesives of which the properties have been changed in a known way by adding further additives can be used.

One particularly advantageous embodiment of the invention provides that the adhesive bond exists between a chip and a carrier substrate, as is required for the packaging of the chip. In particular, this mechanical connection of the silicon material of the chip and the plastics material of the carrier substrate has the effect that the adhesive bond is subjected to great stress exposure under thermal loads, as occur as a result of necessary alternating temperature tests and burn-ins. Therefore, increasing the reliability of the mechanical connection by positioning the surfaces to be bonded in parallel, and consequently by reducing the stress within the adhesive bond, is of extremely great significance in particular in this principal application.

If the carrier substrate has on the underside a metallization and solder balls arranged in the manner of a grid and distributed in a flat array (BGA) and/or a solder stop mask on one or both sides for limiting the solder flow during the electrical contacting of the substrate-based semiconductor device, these changed adhering conditions and also the respectively occurring thermal stress conditions can be counteracted by variation of the fillers in the way already described.

The figure shows the attachment of an unpackaged chip 1 on a carrier substrate 2, which on the underside has solder balls 3 arranged in the manner of a grid in a flat array (BGA). The chip 1 is in this case mounted with the side having the electrical terminals 4 downwards (face-down) in such a way that the central terminal region 5 is located over a through-hole 6 in the carrier substrate 2, and consequently the electrical terminals 4 of the chip 1 are electrically connected to the bonding pads 8 of the carrier substrate 2 by means of wire bridges 7 running through the through-hole 6.

The mechanical attachment of the chip is performed with a layer of adhesive 9, which extends over the entire surface area of the chip 1, except for the terminal region 5, and contains uniformly distributed spherical filling bodies 10 with two different diameters.

An underside metallization 11 of the carrier substrate 2 electrically connects the bonding pads 8 to the solder balls 3 by means of its own wiring patterns. This metallization 11 is covered by a first solder stop mask 12, which leaves the through-hole 6, the bonding pads 8 and the pads carrying the solder balls 13 free. On the side facing the chip 1, the carrier substrate 2 has a second solder stop mask 14, which is consequently located between the layer of adhesive 9 and the carrier substrate 2 and which only leaves the through-hole 6 free.

1. A method for producing an adhesive bond between two planar surfaces, the method comprising:
applying a flexible coupling agent on a first planar surface over the extent of its area; and
bonding the first planar surface to a second planar surface by bringing the second planar surface into contact with the coupling agent and keeping the coupling agent contact under conditions required for forming a bond until the coupling agent has formed a stable bond between the first and second planar surfaces, wherein a distance between the first and second planar surfaces is set to a size that corresponds at least to a desired thickness of the coupling medium by the adhesive bond in such a way that it is self-leveling and approximately constant over the surface area.

2. The method according to claim 1, and further comprising admixing filling bodies with a round cross-section and a defined diameter, at least some of the filling bodies having a maximum diameter that corresponds at most to the distance to be set, with the coupling agent.

3. The method according to claim 2, wherein the filling bodies have different diameters.

4. The method according to claim 2, wherein the filling bodies have the same diameter.

5. The method according to claim 1, wherein the coupling agent comprises a pasty adhesive that is capable of being printed.

6. The method according to claim 5, and further comprising admixing further additives that change the properties of the coupling medium with the coupling medium.

7. The method according to claim 1, wherein the first planar surface comprises a surface of a semiconductor chip and the second planar surface comprises a surface of a carrier substrate.

8. The method according to claim 1, wherein the second planar surface comprises a surface of a semiconductor chip and the first planar surface comprises a surface of a carrier substrate.

9. A method of packaging a semiconductor chip, the method comprising:
applying a coupling agent to a surface of a semiconductor chip, the coupling agent comprising filling bodies with a substantially round cross-section, at least some of the filling bodies having a maximum diameter;
bringing a carrier substrate into contact with the coupling agent; and
maintaining contact between the carrier substrate and the coupling agent at a predetermined distance that is greater than or equal to the maximum diameter, the maintaining occurring until a stable bond is formed between the carrier substrate and the semiconductor chip, wherein the stable bond is formed form a substantially uniform thickness layer of the coupling agent.

10. The method of claim 9, wherein the filling bodies have different diameters.

11. The method of claim 9, wherein the filling bodies have the same diameter.

12. An electronic component comprising:
a semiconductor chip;
a substrate carrier spaced from the semiconductor chip by a distance; and
an adhesive bond attaching the semiconductor chip to the substrate carrier, the adhesive bond comprising a flexible coupling medium that is spread virtually over substantially an entire surface of the chip, apart from a region serving for the electrical contacting, wherein the adhesive bond further comprises filling bodies with a round cross-section and a defined diameter, at least some of which have a maximum diameter which correspond at most to the distance.

13. The electronic component according to claim 12, wherein the filling bodies are spherical.

14. The electronic component according to claim 12, wherein the filling bodies have at least two different diameters.

15. The electronic component according to claim 12, wherein the filling bodies are reversibly deformable.

16. The electronic component according to claim 15, wherein the reversible deformability of the filling bodies differs.

17. The electronic component according to claim 12, wherein the coupling medium comprises a pasty material that is capable of being printed.

18. The electronic component according to claim 17, wherein the coupling medium contains further additives that change its properties.

19. The electronic component according to claim 12, wherein the carrier substrate includes on the underside a metallization and solder balls arranged in the manner of a grid and distributed in a flat array.

20. The electronic component according to claim 12, wherein the carrier substrate includes a solder stop mask on at least one surface.
